(19) United States
(12) Patent Application Publication
(10) Pub. No.: US 2025/0386683 A1
(43) Pub. Date: Dec. 18, 2025

(54) DISPLAY PANEL

(71) Applicant: HANNSTAR DISPLAY CORPORATION, Taipei City (TW)

(72) Inventors: Yu-Chi Chiao, Taipei City (TW); Hsu-Ho Wu, Tainan City (TW); I-Tung Chen, New Taipei City (TW); Jhih-Jie Huang, Miaoli County (TW); Chiung-Chang Wu, Tainan City (TW)

(73) Assignee: HANNSTAR DISPLAY CORPORATION, Taipei City (TW)

(21) Appl. No.: 18/957,884

(22) Filed: Nov. 25, 2024

(30) Foreign Application Priority Data
Jun. 13, 2024 (TW) 113121827

(51) Int. Cl. H10K 59/126; H10K 59/131

(52) U.S. Cl. CPC H10K 59/126; H10K 59/131

(57) ABSTRACT

A display panel including a substrate, a thin film transistor, a color resist protective layer and a conductive layer is disclosed. The thin film transistor is disposed on the substrate. The color resist protective layer is disposed on the thin film transistor and the substrate. The color resist protective layer is overlapped with the thin film transistor in a normal direction of the substrate, and the color resist protective layer includes a first opening. The color resist protective layer is used for absorbing a light with wavelength in at least a portion of visible-light wavelength range. The conductive layer is disposed on the color resist protective layer and electrically connected to the thin film transistor through the first opening.

### BACKGROUND OF THE INVENTION

### 1. Field of the Invention

The present invention relates to a display panel, and more particularly to a display panel including a color resist protective layer.

### 2. Description of the Prior Art

Display panels are used to transmit and display information more conveniently, and have been widely applied in various electronic products, such as notebooks, smart phones, wearable devices, smart watches and display screens for vehicles. However, reflected light produced by light (such as ambient light and/or light provided by a light-emitting module) illuminating the layers and elements in a display panel may affect the color contrast, and the light illuminating the electronic elements may further cause the photo-leakage. Therefore, the architectural design of the layers of a display panel is still one of the important issues in the current field.

### SUMMARY OF THE INVENTION

One of the objectives of the present invention is to provide a display panel, wherein a color resist protective layer is capable of absorbing light and is overlapped with a thin film transistor, which may prevent stray light from being reflected or passing through the display panel, thereby reducing photo-leakage current and improving color contrast. The color resist protective layer may also serve as a planarization layer.

In order to achieve the above objectives, the present invention provides a display panel including a substrate, a thin film transistor, a color resist protective layer and a conductive layer. The thin film transistor is disposed on the substrate. The color resist protective layer is disposed on the thin film transistor and the substrate. The color resist protective layer is overlapped with the thin film transistor in a normal direction of the substrate, and the color resist protective layer includes a first opening. The color resist protective layer is used for absorbing a light with wavelength in at least a portion of visible-light wavelength range. The conductive layer is disposed on the color resist protective layer, and the conductive layer is electrically connected to the thin film transistor through the first opening.

According to the display panels of the embodiments of the present invention, the disclosed structural design wherein the color resist protective layer capable of absorbing light is disposed on the thin film transistor and the substrate may prevent stray light from being reflected, scattered or passing through the layer-stacking structure of the display panel, thereby improving the color contrast. In addition, the color resist protective layer may serve as a planarization layer to flatten the landform, and the color resist protective layer overlapped with the thin film transistor may further serve as a light-shielding layer to reduce the photo-leakage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial cross-sectional schematic diagram of a display panel according to a first embodiment of the present invention.

FIG. 2 is a partial cross-sectional schematic diagram of a display panel according to a second embodiment of the present invention.

FIG. 3 is a partial cross-sectional schematic diagram of a display panel according to a third embodiment of the present invention.

FIG. 4 is a partial cross-sectional schematic diagram of a display panel according to a fourth embodiment of the present invention.

FIG. 5 is a partial cross-sectional schematic diagram of a display panel according to a fifth embodiment of the present invention.

FIG. 6 is a partial cross-sectional schematic diagram of a display panel according to a sixth embodiment of the present invention.

FIG. 7 is a partial cross-sectional schematic diagram of a display panel according to a seventh embodiment of the present invention.

FIG. 8 is a partial cross-sectional schematic diagram of a display panel according to an eighth embodiment of the present invention.

FIG. 9 is a partial cross-sectional schematic diagram of a display panel according to a ninth embodiment of the present invention.

### DETAILED DESCRIPTION

For understanding the present invention, the features and desired effects of the present invention are described in detail with reference to the following embodiments, taken in conjunction with the drawings. It should be noted that the drawings are simplified schematic diagrams, so that only the components and their relationships related to the present invention are shown in order to provide a clear description of the basic architecture or implementation of the present invention. It will be understood by one skilled in the art that the practical components and layout may be more detailed. In addition, for the convenience of illustration, the components shown in various drawings of the present invention are not drawn in proportion with respect to their actual number, shape and size in practice, and the detailed proportions thereof may be adjusted according to the design requirements.

In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present invention, the corresponding features, areas, steps, operations and/or components are not limited to the specific embodiment, and the addition of one or a plurality of the corresponding or other features, areas, steps, operations, components and/or combinations thereof are also included in the scope of the application.

The ordinal numbers used in the description and claims, such as “first”, “second”, “third”, etc., are used to describe elements, but they do not mean or represent that the element(s) have any previous ordinal numbers, nor do they represent the order of one element and another element, or the order of manufacturing methods. The ordinal numbers are used only to clearly distinguish an element with a certain name from another element with the same name. The claims and the description may not use the same terms. Accordingly, a first constituent element in the following description may be a second constituent element in a claim.

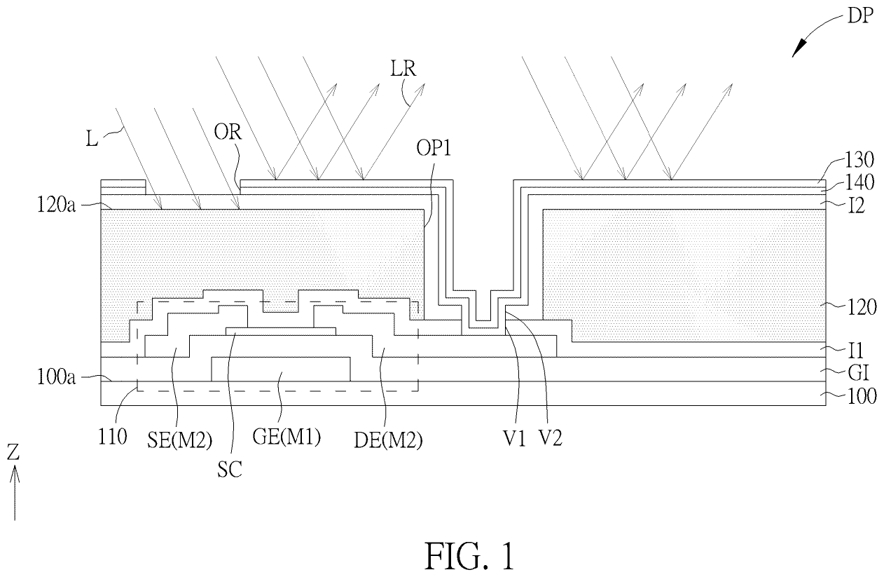

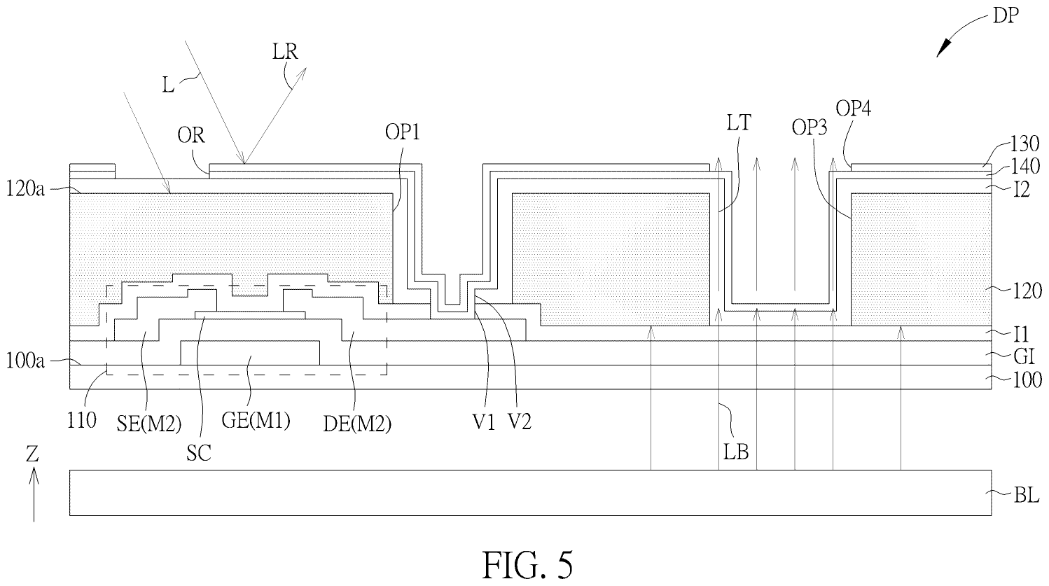

In the present invention, a display panel may be used in a non-self-emissive display device or a self-emissive display device. The display panel may be a reflective type display panel (as shown in FIG. 1 to FIG. 4) or a transflective type display panel (as shown in FIG. 5 to FIG. 9), a transmissive type display panel or other suitable display panels. The display panel may include a liquid crystal display panel or other suitable display panels. For example, the display panel may include a thin film transistor substrate and a color filter substrate which are disposed opposite to each other, where a display media layer is disposed between the thin film transistor substrate and the color filter substrate, but the structure of the display panel is not limited to the above. The display media layer includes, for example, liquid crystals or light-emitting diodes. The light-emitting diode may include an organic light-emitting diode (OLED), a mini light-emitting diode (mini LED) or a micro light-emitting diode (micro LED), but is not limited herein.

The reflective type display panel may use an external light as a light source for displaying images. The external light enters the display panel from a side of the display panel facing a user, and the display panel reflects the external light to display a corresponding image, wherein the external light described above may be ambient light (e.g., solar light), but not limited herein. In some embodiments, the display panel may further include a front-light module, and the external light described above may further include the light provided from the front-light module, wherein the front-light module is disposed at the side of the display panel facing the user. The transflective type display panel may further include a backlight module, wherein in addition to using the above external light as a light source for displaying images, the transflective type display panel may further use the light provided from the backlight module as another light source for displaying images, and the backlight module is disposed at a side of the display panel facing away from the user, but not limited herein.

It should be noted that the technical features in different embodiments described in the following can be replaced, recombined, or mixed with one another to constitute another embodiment without departing from the spirit of the present invention.

Refer to FIG. 1, which is a partial cross-sectional schematic diagram of a display panel according to a first embodiment of the present invention. As shown in FIG. 1, a display panel DP includes a substrate 100, a thin film transistor 110, a color resist protective layer 120 and a conductive layer 130. The substrate 100 may include a hard substrate or a flexible substrate. The hard substrate includes, for example, glass, ceramics, quartz or sapphire, and the flexible substrate includes, for example, polyimide (PI), polycarbonate (PC), polyethylene terephthalate (PET) or poly(methyl methacrylate) (PMMA), but not limited herein. The thin film transistor 110 is disposed on the substrate 100, wherein the thin film transistor 110 may serve as, for example (but not limited to), a driving element or a switching element of a pixel. The thin film transistor 110 may include a drain DE, a source SE, a gate GE and a semiconductor layer SC, and an insulating layer GI is provided between the gate GE and the semiconductor layer SC, which may serve as a gate insulating layer in the thin film transistor 110. It should be noted that the stacking of layers of the thin film transistor 110 shown in FIG. 1 is only one of various examples, and the present invention is not limited herein.

The color resist protective layer 120 is disposed on the thin film transistor 110 and the substrate 100, and the color resist protective layer 120 is overlapped with the thin film transistor 110 in a direction Z, wherein the direction Z is a normal direction of the substrate 100, i.e., the direction Z may be parallel to the normal direction of an upper surface 100a or a lower surface of the substrate 100. The color resist protective layer 120 has a planar upper surface 120a on a side opposite to the substrate 100. The color resist protective layer 120 covers the thin film transistor 110 and the substrate 100, and the color resist protective layer 120 may serve as a planarization layer to flatten the landform, wherein the color resist protective layer 120 covers the elements or wires below to provide a planar upper surface. The color resist protective layer 120 includes a first opening OP1. The conductive layer 130 is disposed on the color resist protective layer 120, and the conductive layer 130 is electrically connected to the thin film transistor 110 through the first opening OP1. As shown in FIG. 1, a portion of the conductive layer 130 may be located in the first opening OP1 and electrically connected to the drain DE of the thin film transistor 110 through the first opening OP1. The display panel DP may include a liquid crystal layer (not shown) disposed on the conductive layer 130, and therefore the color resist protective layer 120 with a planar surface may make the cell gap of the liquid crystal layer have a small degree of variation, thereby improving the quality of displayed images.

In the present invention, the color resist protective layer 120 is used for absorbing a light L with wavelength in at least a portion of visible-light wavelength range, thereby preventing unnecessary light or stray light from passing through the layer-stacking structure of the display panel DP or being reflected or scattered therein, wherein the light L may be ambient light (e.g., solar light) and/or light provided by the front-light module. The color resist protective layer 120 may include one of black color resist, blue color resist, green color resist and red color resist. In some embodiments, when the color resist protective layer 120 includes the black color resist, it may be used for absorbing the light L in all of a visible-light wavelength range, thereby preventing stray light from being reflected or passing through, so as to improve the color contrast. Furthermore, the color resist protective layer 120 may also serve as a light-shielding layer, to block the light from passing through and illuminating the thin film transistor 110 below, thereby reducing the probability of the occurrence of photo-leakage current. In addition, the display panel DP may usually include a black matrix (BM) disposed on a side of another substrate (such as a color filter substrate) opposite to the substrate 100, while the color resist protective layer 120 provided in the present invention may be used to replace the function of the black matrix, and the decrease in the aperture ratio and/or reflectivity caused by the alignment accuracy error of the black matrix in the prior art may be reduced. In other embodiments, when the color resist protective layer 120 includes a color resist that absorbs light in other specific wavelength range, i.e., when the color resist protective layer 120 is used for absorbing the light L having a wavelength in a portion of a visible-light wavelength range, the function of adjusting color gamut of the panel may be achieved. For example, the visual effect offsetting to yellow may be improved when the color resist protective layer 120 includes blue color resist, the contrast of the panel may be improved when the color resist protective layer 120 includes green color resist, and the visual fatigue may be improved when the color resist protective layer 120 includes red color resist.

According to the embodiment shown in FIG. 1, the display panel DP may be a reflective type display panel, wherein the conductive layer 130 may be a metal layer used for reflecting the light L to form a reflected light LR to display images. The color resist protective layer 120 serving as the planarization layer may maintain the flatness of the conductive layer 130, to obtain stable reflected light LR. Furthermore, the display panel DP may further include a transparent conductive layer 140 disposed between the conductive layer 130 and the color resist protective layer 120, and the transparent conductive layer 140 may be electrically connected to the thin film transistor 110 through the first opening OP1 of the color resist protective layer 120. The transparent conductive layer 140 may serve as a pixel electrode, and the transparent conductive layer 140 has an opening region OR, so that electrodes of adjacent pixels may be separated from each other. In the region other than the opening region OR, the conductive layer 130 may be correspondingly disposed on the transparent conductive layer 140. The light L entering the opening region OR may be absorbed by the color resist protective layer 120 to prevent the stray light from passing through the layer-stacking structure of the display panel DP or being reflected or scattered therein. The structure of the pixel electrode in the present invention is not limited to the above, however. In some embodiments, the conductive layer 130 may serve as both a metal reflective layer and a pixel electrode and have an opening region, without an additional transparent conductive layer 140. In other embodiments, the conductive layer 130 may be a transparent conductive layer and serve as a pixel electrode, so that the formed display panel DP may be a transmissive type display panel, wherein the transparent conductive layer 140 may not be required.

As shown in FIG. 1, the display panel DP may include, for example, a conductive layer M1 forming the gate GE, the insulating layer GI forming the gate insulating layer, the semiconductor layer SC, a conductive layer M2 forming the drain DE and the source SE, an insulating layer I1, the color resist protective layer 120, an insulating layer I2, the transparent conductive layer 140, and the conductive layer 130, which are disposed on the upper surface 100a of the substrate 100 in sequence along the direction Z. The insulating layer I1 may have a hole V1 exposing a portion of the drain DE, and the first opening OP1 of the color resist protective layer 120 is partially overlapped with the hole V1 in the direction Z. A portion of the insulating layer I2 is disposed in the first opening OP1 to cover the sidewall of the first opening OP1, and the insulating layer I2 has a hole V2 which is overlapped with the hole V1 in the direction Z. The transparent conductive layer 140 and the conductive layer 130 may contact and be electrically connected to the drain DE of the thin film transistor 110 through the hole V2 and the hole V1 within the first opening OP1.

The display panel of the present invention is not limited to the above embodiments.

Some embodiments of the display panels of the present invention will be detailed in the following. In order to simplify the illustration, the same elements in the present invention will be labeled with the same symbols. The differences between different embodiments are described in detail below, wherein same features are not described again for the sake of brevity.

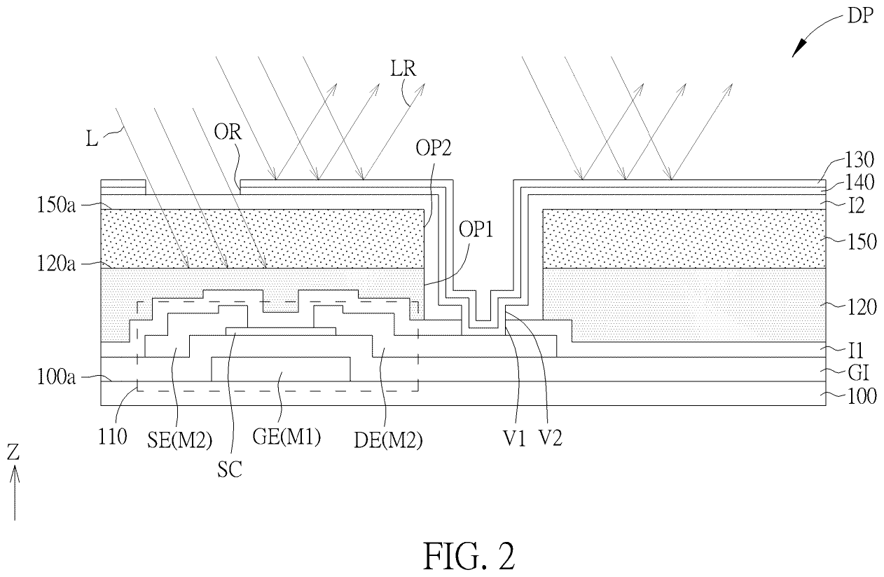

Refer to FIG. 2, which is a partial cross-sectional schematic diagram of a display panel according to a second embodiment of the present invention. The difference between the display panel DP of the second embodiment shown in FIG. 2 and the first embodiment shown in FIG. 1 is that the display panel DP may further include a transparent protective layer 150 disposed on the substrate 100, and the transparent protective layer 150 may be at least partially overlapped with the color resist protective layer 120 in the direction Z, wherein the transparent protective layer 150 is disposed between the color resist protective layer 120 and the conductive layer 130. Specifically, as shown in FIG. 2, the color resist protective layer 120 may be disposed on the insulating layer I1, and the transparent protective layer 150 may be disposed on the color resist protective layer 120 and cover the surface of the color resist protective layer 120 blanketly. The insulating layer I2, the transparent conductive layer 140 and the conductive layer 130 may be disposed on the transparent protective layer 150 in sequence along the direction Z. The transparent protective layer 150 may include a second opening OP2, and the second opening OP2 of the transparent protective layer 150 is overlapped with the first opening OP1 of the color resist protective layer 120 in the direction Z. The conductive layer 130 may be electrically connected to the thin film transistor 110 through the second opening OP2 of the transparent protective layer 150 and the first opening OP1 of the color resist protective layer 120. As shown in FIG. 2, the transparent conductive layer 140 may contact and be electrically connected to the drain DE of the thin film transistor 110 through the hole V2 and the hole V1 within the second opening OP2 and the first opening OP1, and the conductive layer 130 may be connected to the transparent conductive layer 140.

According to the embodiment shown in FIG. 2, the light L entering the opening region OR may pass through the transparent protective layer 150 and be absorbed by the color resist protective layer 120, thereby preventing stray light from passing through the layer-stacking structure, or being reflected or scattered therein. The color resist protective layer 120 has a planar upper surface 120a at the side opposite to the substrate 100, and the transparent protective layer 150 has a planar upper surface 150a at the side opposite to the color resist protective layer 120, so that both the transparent protective layer 150 and the color resist protective layer 120 may serve as planarization layers. The transparent protective layer 150 and the color resist protective layer 120 serve as two planarization layers in this embodiment, so that the layer-stacking structure has better flatness compared with one planarization layer. For example, the conductive layer 130 disposed as the uppermost layer in FIG. 2 may have better flatness to obtain more stable reflected light LR, or the cell gap of the liquid crystal layer (not shown) disposed on the conductive layer 130 may have a small degree of variation, thereby improving the quality of displayed images.

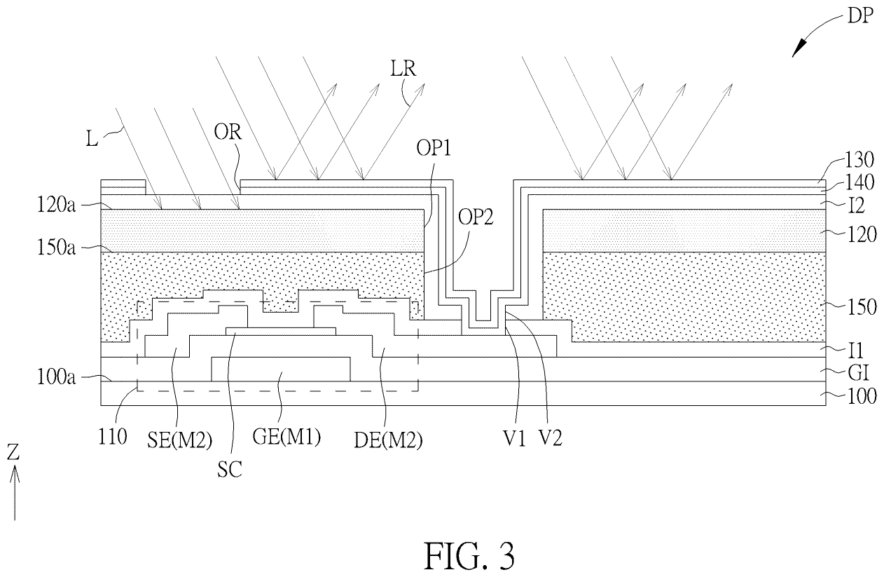

Refer to FIG. 3, which is a partial cross-sectional schematic diagram of a display panel according to a third embodiment of the present invention. The difference between a display panel DP of the third embodiment shown in FIG. 3 and the second embodiment shown in FIG. 2 is that the transparent protective layer 150 is disposed between the color resist protective layer 120 and the substrate 100. Specifically, as shown in FIG. 3, the transparent protective layer 150 may be disposed on the insulating layer I1, and the color resist protective layer 120 may be disposed on the transparent protective layer 150 and cover the surface of the transparent protective layer 150 blanketly. The insulating layer I2, the transparent conductive layer 140 and the conductive layer 130 may be disposed on the color resist protective layer 120 in sequence along the direction Z. The transparent protective layer 150 may include a second opening OP2, and the second opening OP2 of the transparent protective layer 150 is overlapped with the first opening OP1 of the color resist protective layer 120 in the direction Z. The conductive layer 130 may be electrically connected to the thin film transistor 110 through the first opening OP1 of the color resist protective layer 120 and the second opening OP2 of the transparent protective layer 150. As shown in FIG. 3, the transparent conductive layer 140 may contact and be electrically connected to the drain DE of the thin film transistor 110 through the hole V2 and the hole V1 within the first opening OP1 and the second opening OP2, and the conductive layer 130 may be connected to the transparent conductive layer 140.

According to the embodiment shown in FIG. 3, the light L entering the opening region OR may be absorbed by the color resist protective layer 120, thereby preventing stray light from passing through the layer-stacking structure of the display panel DP, or being reflected or scattered therein. Similarly, the transparent protective layer 150 and the color resist protective layer 120 serve as two planarization layers in this embodiment, so that the layer-stacking structure has better flatness compared with one planarization layer.

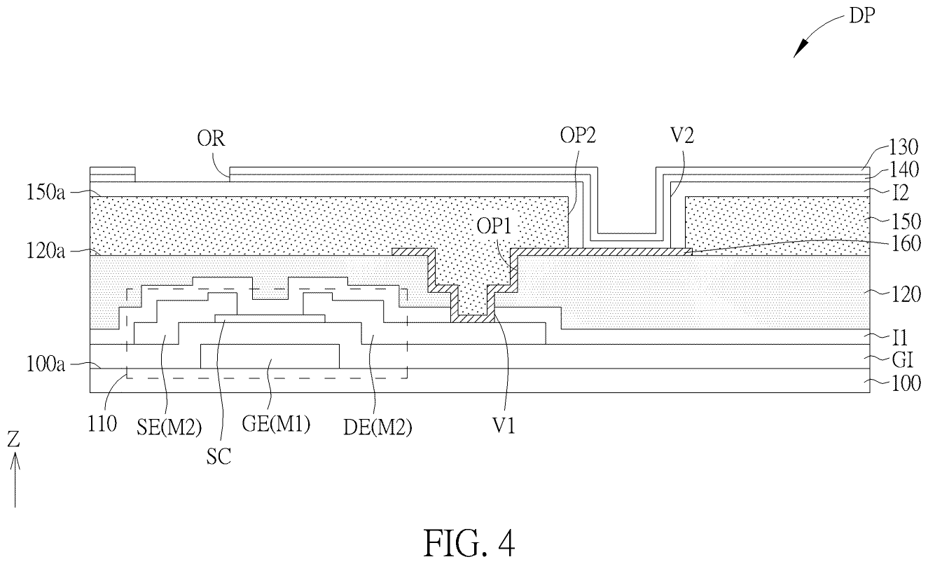

Refer to FIG. 4, which is a partial cross-sectional schematic diagram of a display panel according to a fourth embodiment of the present invention. According to the embodiment shown in FIG. 4, the display panel DP may further include a conductive layer 160 disposed between the transparent protective layer 150 and the color resist protective layer 120. Furthermore, the second opening OP2 of the transparent protective layer 150 is not overlapped with the first opening OP1 of the color resist protective layer 120 in the direction Z, and the conductive layer 130 and the transparent conductive layer 140 may be electrically connected to the conductive layer 160 through the second opening OP2 and further electrically connected to the thin film transistor 110 through the conductive layer 160. That is to say, the conductive layer 160 may serve as a bridge layer between the first opening OP1 and the second opening OP2. In this embodiment, the second opening OP2 and the first opening OP1 are located at different positions and do not overlap each other, so that the thickness of the photoresist is not too thick, which would cause poor exposure and development when the second opening OP2 is formed in an exposure and development process. Specifically, as shown in FIG. 4, the insulating layer I1 may have a hole V1 exposing a portion of the drain DE, and the first opening OP1 of the color resist protective layer 120 is partially overlapped with the hole V1 in the direction Z. The conductive layer 160 may contact and be electrically connected to the drain DE of the thin film transistor 110 through the first opening OP1 and the hole V1, and a portion of the conductive layer 160 is disposed on the upper surface 120a of the color resist protective layer 120. The transparent protective layer 150 is disposed on the conductive layer 160 and the color resist protective layer 120 and filled in the first opening OP1 of the color resist protective layer 120, wherein the second opening OP2 of the transparent protective layer 150 is not overlapped with the first opening OP1 and exposes a portion of the conductive layer 160 disposed on the upper surface 120a of the color resist protective layer 120. A portion of the insulating layer 12 may be disposed in the second opening OP2 to cover the sidewall thereof, and the insulating layer I2 has a hole V2 overlapped with the second opening OP2 in the direction Z. The transparent conductive layer 140 may contact and be electrically connected to the conductive layer 160 through the hole V2 within the second opening OP2, and the conductive layer 130 may be connected to the transparent conductive layer 140.

In some embodiments, the positions of the transparent protective layer 150 and the color resist protective layer 120 shown in FIG. 4 may be exchanged with each other, such that the transparent protective layer 150 may be the lower layer, and the color resist protective layer 120 may be the upper layer. In some embodiments, the conductive layer 160 disposed between the transparent protective layer 150 and the color resist protective layer 120 may be a transparent conductive layer, but the present invention is not limited herein. In other embodiments, the conductive layer 160 may be a non-transparent metal layer.

Refer to FIG. 5, which is a partial cross-sectional schematic diagram of a display panel according to a fifth embodiment of the present invention. As shown in FIG. 5, the display panel DP may further include a backlight module BL disposed at a side of the substrate 100 opposite to the thin film transistor 110. Furthermore, the color resist protective layer 120 further includes a third opening OP3, and a backlight LB emitted from the backlight module BL is capable of passing through the third opening OP3. According to the embodiment shown in FIG. 5, the display panel DP may be a transflective type display panel. The conductive layer 130 may be a metal layer and includes a fourth opening OP4, and the fourth opening OP4 is overlapped with the third opening OP3 in the direction Z. The display panel DP may further include a transparent conductive layer 140 disposed between the conductive layer 130 and the color resist protective layer 120, and a portion of the transparent conductive layer 140 is disposed corresponding to the third opening OP3 of the color resist protective layer 120.

Specifically, the conductive layer 130 is a metal layer and is used for reflecting the light L to form the reflected light LR to display images, wherein the light L may be ambient light and/or light provided by the front-light module, and the color resist protective layer 120 may serve as a planarization layer and absorb the light L entering the opening region OR. The detailed description related to the opening region OR may refer to the first embodiment shown in FIG. 1, which will not be described again for brevity. The backlight LB emitted by the backlight module BL is capable of passing through the third opening OP3 and the fourth opening OP4 to display images when the backlight module BL is turned on, and the backlight LB can be absorbed by the color resist protective layer 120 in the region other than the opening OP3, to prevent stray light from passing through the layer-stacking structure of the display panel DP or being reflected or scattered many times therein which generates heat energy. Furthermore, the color resist protective layer 120 absorbs the light L to prevent photo-leakage current caused by stray light illuminating the thin film transistor 110, thereby improving the stability of the thin film transistor 110.

As shown in FIG. 5, the insulating layer I1 may be disposed on the substrate 100, and the third opening OP3 of the color resist protective layer 120 may expose a portion of the insulating layer I1. A portion of the insulating layer 12 may be disposed in the third opening OP3 to cover the sidewall thereof, and a portion of the transparent conductive layer 140 may be disposed in the third opening OP3 and disposed on the insulating layer I2. The region where the third opening OP3 overlaps the fourth opening OP4 may serve as a transmittive region, so that the backlight LB emitted by the backlight module BL may pass through the transmittive region (for example, but not limited to, passing through the substrate 100, the insulating layer GI, the insulating layer I1, the insulating layer I2 and the transparent conductive layer 140 in sequence) to form a transmitting light LT for displaying images.

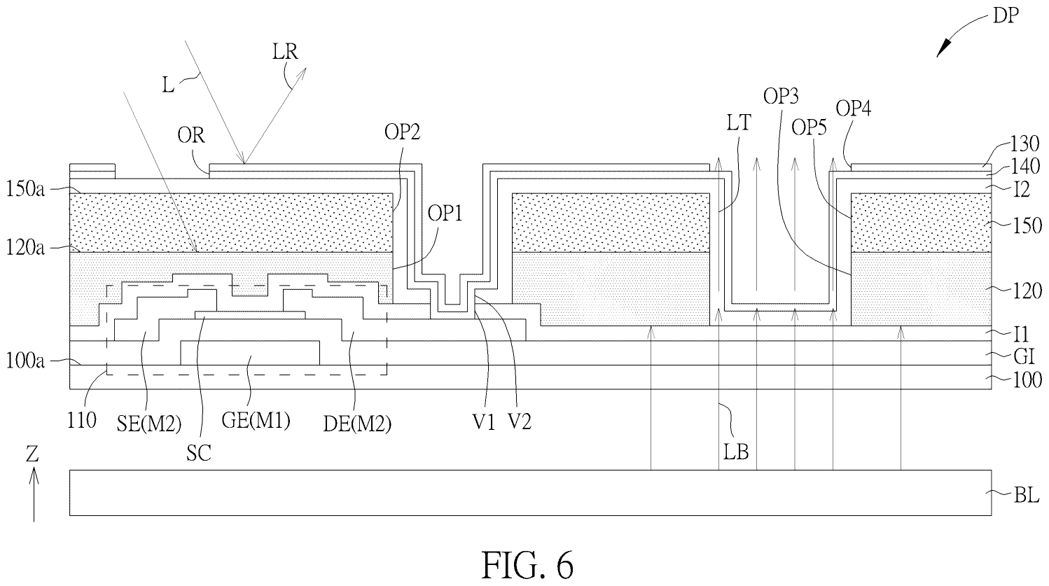

Refer to FIG. 6, which is a partial cross-sectional schematic diagram of a display panel according to a sixth embodiment of the present invention. The difference between the display panel DP of the sixth embodiment shown in FIG. 6 and the fifth embodiment shown in FIG. 5 is that the display panel DP further includes a transparent protective layer 150 disposed on the substrate 100, and the transparent protective layer 150 is at least partially overlapped with the color resist protective layer 120 in the direction Z. As shown in FIG. 6, the transparent protective layer 150 is disposed between the color resist protective layer 120 and the conductive layer 130. For example, the color resist protective layer 120 may be disposed on the insulating layer 11, and the transparent protective layer 150 may be disposed on the color resist protective layer 120 and cover the surface of the color resist protective layer 120 blanketly. The transparent protective layer 150 includes a fifth opening OP5 overlapped with the third opening OP3 in the direction Z, and the backlight LB emitted by the backlight module BL is capable of passing through the third opening OP3, the fifth opening OP5 and the fourth opening OP4 in sequence. That is to say, the region corresponding to the third opening OP3 of the color resist protective layer 120, the fifth opening OP5 of the transparent protective layer 150 and the fourth opening OP4 of the conductive layer 130 may form a transmittive region, so that the backlight LB emitted by the backlight module BL may pass through the transmittive region (for example, but not limited to, passing through the substrate 100, the insulating layer GI, the insulating layer I1, the insulating layer I2 and the transparent conductive layer 140 in sequence) to form the transmitting light LT for displaying images. In this embodiment, the transparent protective layer 150 and the color resist protective layer 120 serving as two planarization layers may make the layer-stacking structure have better flatness.

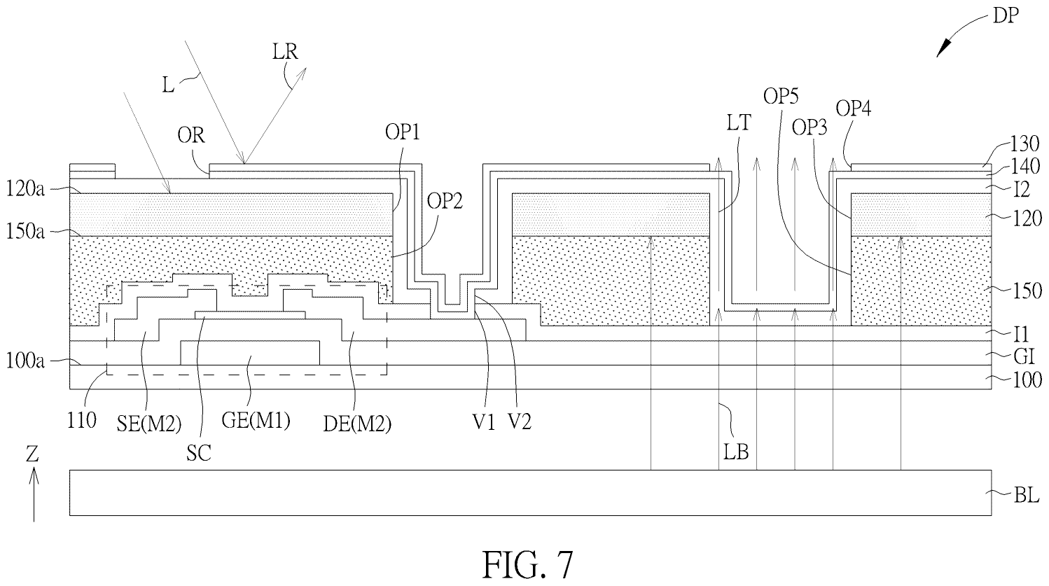

Refer to FIG. 7, which is a partial cross-sectional schematic diagram of a display panel according to a seventh embodiment of the present invention. The difference between the display panel DP of the seventh embodiment shown in FIG. 7 and the sixth embodiment shown in FIG. 6 is that the transparent protective layer 150 is disposed between the color resist protective layer 120 and the substrate 100. For example, the transparent protective layer 150 may be disposed on the insulating layer I1, and the color resist protective layer 120 may be disposed on the transparent protective layer 150 and cover the surface of the transparent protective layer 150 blanketly. The transparent protective layer 150 includes a fifth opening OP5 overlapped with the third opening OP3 in the direction Z, and the backlight LB emitted by the backlight module BL is capable of passing through the fifth opening OP5, the third opening OP3 and the fourth opening OP4 in sequence. That is to say, the region corresponding to the fifth opening OP5 of the transparent protective layer 150, the third opening OP3 of the color resist protective layer 120 and the fourth opening OP4 of the conductive layer 130 may form a transmittive region, so that the backlight LB emitted by the backlight module BL may pass through the transmittive region (for example, passing through the substrate 100, the insulating layer GI, the insulating layer I1, the insulating layer I2 and the transparent conductive layer 140 in sequence) to form the transmitting light LT for displaying images. In this embodiment, the backlight LB may pass through the transparent protective layer 150 and be absorbed by the color resist protective layer 120, to prevent stray light from passing through the layer-stacking structure of the display panel DP or being reflected therein resulting in illuminating the thin film transistor 110.

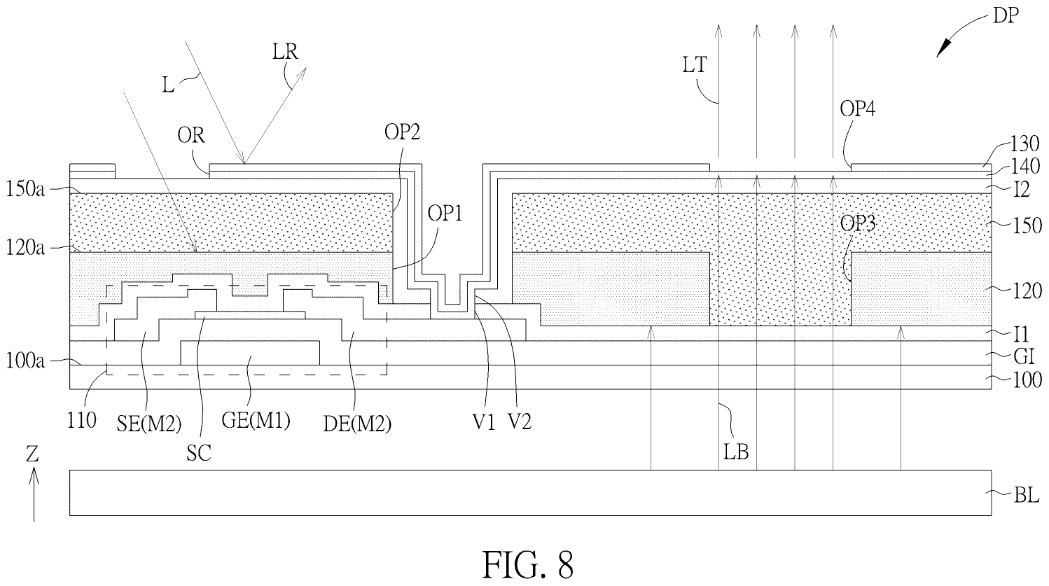

Refer to FIG. 8, which is a partial cross-sectional schematic diagram of a display panel according to an eighth embodiment of the present invention. The difference between the display panel DP of the eighth embodiment shown in FIG. 8 and that of the sixth embodiment shown in FIG. 6 is that a portion of the transparent protective layer 150 is filled in the third opening OP3 of the color resist protective layer 120. That is to say, the transparent protective layer 150 may be disposed between the color resist protective layer 120 and the conductive layer 130, and the transparent protective layer 150 has no opening at the position corresponding to the third opening OP3. Specifically, as shown in FIG. 8, the color resist protective layer 120 may be disposed on the insulating layer I1 and include the third opening OP3, and the transparent protective layer 150 is disposed on the color resist protective layer 120 and filled in the third opening OP3. The insulating layer I2 is disposed on the transparent protective layer 150, the transparent conductive layer 140 is disposed on the insulating layer 12, and a portion of the transparent conductive layer 140 is disposed corresponding to the third opening OP3. The conductive layer 130 is disposed on the transparent conductive layer 140, and the fourth opening OP4 of the conductive layer 130 is overlapped with the third opening OP3 of the color resist protective layer 120 in the direction Z and exposes a portion of the transparent conductive layer 140. The region where the third opening OP3, a portion of the transparent protective layer 150, a portion of the transparent conductive layer 140 and the fourth opening OP4 overlap may serve as a transmittive region, so that the backlight LB emitted by the backlight module BL may pass through the transmittive region (for example, but not limited to, passing through the substrate 100, the insulating layer GI, the insulating layer I1, the transparent protective layer 150, the insulating layer I2 and the transparent conductive layer 140 in sequence) to form the transmitting light LT for displaying images. In this embodiment, the transparent protective layer 150 is filled in the third opening OP3 of the color resist protective layer 120 and has a planar upper surface 150a, so that the layer-stacking structure has better flatness. For example, the conductive layer 130 may have better flatness to obtain more stable reflected light LR, or the cell gap of the liquid crystal layer (not shown) disposed on the conductive layer 130 may have a small degree of variation, thereby improving the quality of displayed images.

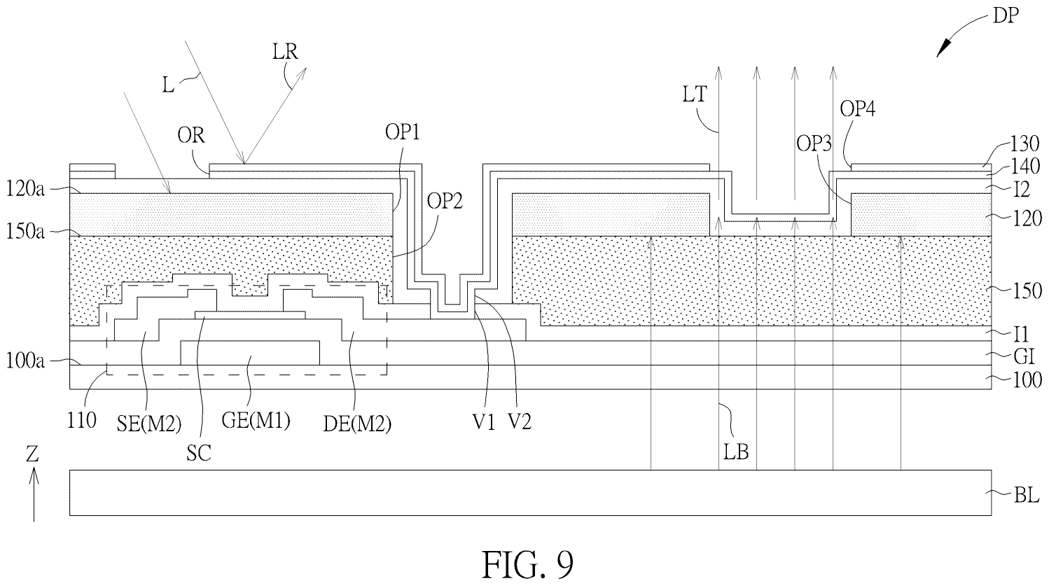

Refer to FIG. 9, which is a partial cross-sectional schematic diagram of a display panel according to a ninth embodiment of the present invention. The difference between the display panel DP of the ninth embodiment shown in FIG. 9 and that of the seventh embodiment shown in FIG. 7 is that the third opening OP3 of the color resist protective layer 120 is overlapped with a portion of the transparent protective layer 150 in the direction Z. That is to say, the transparent protective layer 150 is disposed between the color resist protective layer 120 and the substrate 100, and the transparent protective layer 150 has no opening at the position corresponding to the third opening OP3. Specifically, as shown in FIG. 9, the transparent protective layer 150 may be disposed on the insulating layer I1 and have a planar upper surface 150a, the color resist protective layer 120 is disposed on the transparent protective layer 150 and includes the third opening OP3, and the third opening OP3 exposes a portion of the transparent protective layer 150. The insulating layer I2 is disposed on the color resist protective layer 120, and a portion of the insulating layer I2 is disposed in the third opening OP3 to cover the sidewall thereof. The transparent conductive layer 140 is disposed on the insulating layer 12, and a portion of the transparent conductive layer 140 is disposed in the third opening OP3. The conductive layer 130 is disposed on the transparent conductive layer 140, and the fourth opening OP4 of the conductive layer 130 is overlapped with the third opening OP3 of the color resist protective layer 120 in the direction Z and exposes a portion of the transparent conductive layer 140. The region where a portion of the transparent protective layer 150, the third opening OP3, a portion of the transparent conductive layer 140 and the fourth opening OP4 overlap may serve as a transmittive region, so that the backlight LB emitted by the backlight module BL may pass through the transmittive region (for example, but not limited to, passing through the substrate 100, the insulating layer GI, the insulating layer I1, the transparent protective layer 150, the insulating layer I2 and the transparent conductive layer 140 in sequence) to form the transmitting light LT for displaying images. In this embodiment, the planar upper surface 150a of the transparent protective layer 150 is overlapped with the third opening OP3 of the color resist protective layer 120, so that the layer-stacking structure has better flatness. For example, the conductive layer 130 may have better flatness to obtain more stable reflected light LR, or the cell gap of the liquid crystal layer (not shown) disposed on the conductive layer 130 may have a small degree of variation, thereby improving the quality of displayed images.

From the above description, according to the display panels of the embodiments of the present invention, the provided structural design wherein the color resist protective layer capable of absorbing light is disposed on the thin film transistor and the substrate may prevent stray light from being reflected, scattered or passing through the layer-stacking structure of the display panel, thereby improving the color contrast. Furthermore, the color resist protective layer may serve as a planarization layer to flatten the landform, and the color resist protective layer overlapped with the thin film transistor may further serve as a light-shielding layer to reduce the photo-leakage. In addition, the transparent protective layer and the color resist protective layer may be used as two planarization layers, so that the layer-stacking structure has better flatness.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A display panel, comprising:
a substrate;
a thin film transistor disposed on the substrate;
a color resist protective layer disposed on the thin film transistor and the substrate and overlapped with the thin film transistor in a normal direction of the substrate, wherein the color resist protective layer comprises a first opening, and the color resist protective layer is used for absorbing a light with wavelength in at least a portion of visible-light wavelength range; and
a conductive layer disposed on the color resist protective layer and electrically connected to the thin film transistor through the first opening.

2. The display panel according to claim 1, wherein the color resist protective layer comprises one of black color resist, blue color resist, green color resist and red color resist.

3. The display panel according to claim 1, further comprising a transparent protective layer disposed on the substrate and at least partially overlapped with the color resist protective layer in the normal direction.

4. The display panel according to claim 3, wherein the transparent protective layer is disposed between the color resist protective layer and the conductive layer.

5. The display panel according to claim 3, wherein the transparent protective layer is disposed between the color resist protective layer and the substrate.

6. The display panel according to claim 3, wherein the transparent protective layer comprises a second opening overlapped with the first opening in the normal direction, and the conductive layer is electrically connected to the thin film transistor through the first opening and the second opening.

7. The display panel according to claim 3, further comprising another conductive layer disposed between the transparent protective layer and the color resist protective layer, wherein the transparent protective layer comprises a second opening not overlapped with the first opening in the normal direction, and the conductive layer is electrically connected to the another conductive layer through the second opening and further electrically connected to the thin film transistor through the another conductive layer.

8. The display panel according to claim 1, further comprising a backlight module disposed at a side of the substrate opposite to the thin film transistor, wherein the color resist protective layer further comprises a third opening, and a backlight emitted from the backlight module is capable of passing through the third opening.

9. The display panel according to claim 8, wherein the conductive layer is a metal layer and comprises a fourth opening overlapped with the third opening in the normal direction, the display panel further comprises a transparent conductive layer disposed between the conductive layer and the color resist protective layer, and a portion of the transparent conductive layer is disposed corresponding to the third opening.

10. The display panel according to claim 9, further comprising a transparent protective layer disposed on the substrate and at least partially overlapped with the color resist protective layer in the normal direction.

11. The display panel according to claim 10, wherein the transparent protective layer comprises a fifth opening overlapped with the third opening in the normal direction, and the backlight is capable of passing through the third opening, the fifth opening and the fourth opening.

12. The display panel according to claim 11, wherein the transparent protective layer is disposed between the color resist protective layer and the conductive layer.

13. The display panel according to claim 11, wherein the transparent protective layer is disposed between the color resist protective layer and the substrate.

14. The display panel according to claim 10, wherein the transparent protective layer is disposed between the color resist protective layer and the conductive layer, and a portion of the transparent protective layer is filled in the third opening.

15. The display panel according to claim 10, wherein the transparent protective layer is disposed between the color resist protective layer and the substrate, and the third opening is overlapped with a portion of the transparent protective layer in the normal direction.
